(19) United States
(12) Patent Application Publication
(10) Pub. No.: US 2026/0038765 A1
(43) Pub. Date: Feb. 5, 2026

(54) METHOD FOR GENERATING AN IMAGE OF A SAMPLE, METHOD FOR OPERATING A PARTICLE BEAM MICROSCOPE, PROGRAM, DATA PROCESSING APPARATUS AND PARTICLE BEAM MICROSCOPE

(71) Applicant: Carl Zeiss Microscopy GmbH, Jena (DE)

(72) Inventor: Bjoern GAMM, Koenigsbronn (DE)

(21) Appl. No.: 19/279,329

(22) Filed: Jul. 24, 2025

(30) Foreign Application Priority Data
Aug. 1, 2024 (DE) 10 2024 121 973.4

(51) Int. Cl. H01J 37/22

(52) U.S. Cl. CPC H01J 37/222

(57) ABSTRACT

The present disclosure relates to a method for generating an image of a sample, for example using a particle beam microscope, such as for example a scanning electron microscope. The method comprises calculating the image via a data processing apparatus using interaction product measurement information, using deflection information and using sample stage pose measurement information. The interaction product measurement information represents or is based on results of a measurement of products of an interaction of a particle beam with the sample. The deflection information represents or is based on a deflection of the particle beam during the measurement of the products of the interaction. The sample stage pose measurement information represents or is based on results of a measurement of a measurement variable during the measurement of the products of the interaction. The measurement variable is dependent on a spatial pose of a sample stage carrying the sample.

### CROSS-REFERENCE TO RELATED APPLICATIONS

This application claims benefit under 35 U.S.C. § 119 to German Application No. 10 2024 121 973.4, filed Aug. 1, 2024. The entire disclosure of this application is incorporated by reference herein.

### FIELD

The present disclosure relates to a method of generating an image of a sample, for example using a particle beam microscope, such as for example a scanning electron microscope. The present disclosure relates to a method of operating a particle beam microscope, programs for realizing the methods, a data processing device for executing the programs, and a particle beam microscope.

### BACKGROUND

Particle beam microscopes, such as for example scanning electron microscopes, exist which generate and deflect a particle beam in order to direct the particle beam onto a multiplicity of different locations of a sample and to detect products of an interaction of the particle beam with the sample for the multiplicity of different locations. An image of the sample can be generated from a detection signal representing the detection of the products of the interaction (referred to herein as interaction products), and a control signal representing the deflection of the particle beam. The image comprises a multiplicity of different image points, i.e. positions in the image which each represent a location on the sample, and values assigned to the image points. By way of example, the value assigned to a specific image point represents a number or rate of detections of the interaction products which are detected while the particle beam is directed onto a location of the sample which is represented by the specific image point.

The sample is generally held by a sample stage configured to displace and rotate the sample relative to the particle beam in a plurality of spatial directions. Even if a controller instructs the sample stage to remain in the same pose for a specific time duration, i.e. to keep its position and its orientation constant for the specific time duration, the sample stage in practice often carries out small movements. Such movements are caused for example by external influences, fluctuations in the operating voltage, electrical noise of actuating drives and control elements of the sample stage and the like. The consequence of such movements can be that the control signal representing the deflection of the particle beam represents an incidence location of the particle beam on the sample only inaccurately.

### SUMMARY

The present disclosure addresses the issue of providing a possibility for recording an image of a sample using a particle beam microscope which reduces or eliminates at least some undesirable features related to the above-described uncontrolled movement of a sample stage carrying the sample.

### BRIEF DESCRIPTION OF THE FIGURES

FIG. 1 shows a flowchart illustrating a method for generating an image of a sample in accordance with one embodiment.

FIG. 2 shows a schematic illustration of a spatial relationship between first location information and second location information.

FIG. 3 shows one example of a graphical representation of an image as a scatter diagram.

FIG. 4 shows a flowchart illustrating a method for generating an image of a sample in accordance with a further embodiment.

FIG. 5 shows one example of a graphical representation of an image with regular image points.

FIG. 6 shows a schematic illustration for elucidating an interpolation.

FIG. 7 shows a schematic illustration of a hardware configuration of a data processing apparatus.

FIG. 8 shows a schematic illustration of a particle beam microscope.

### DETAILED DESCRIPTION

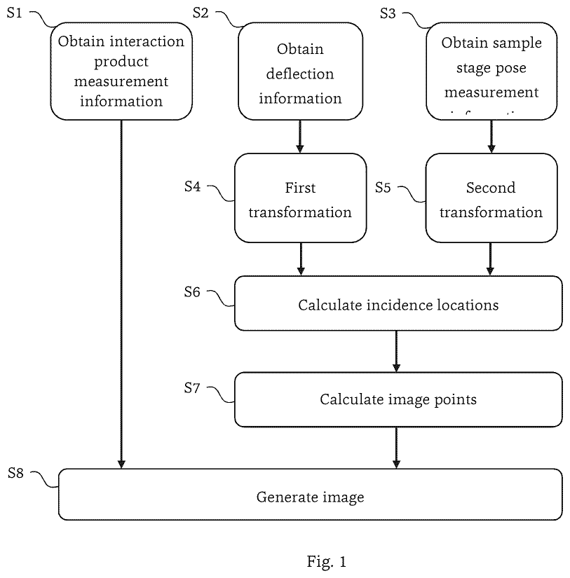

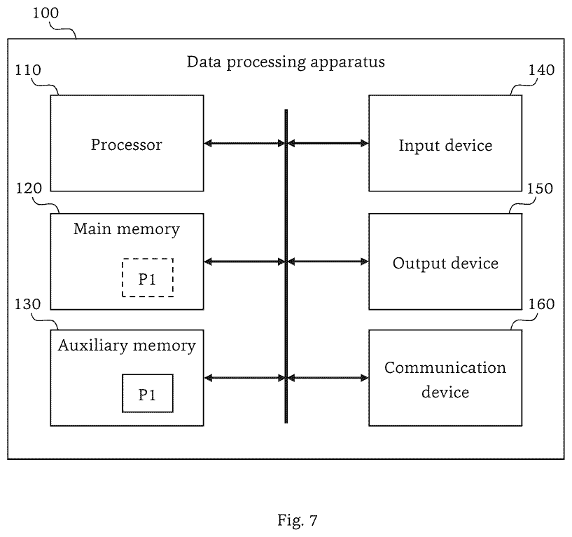

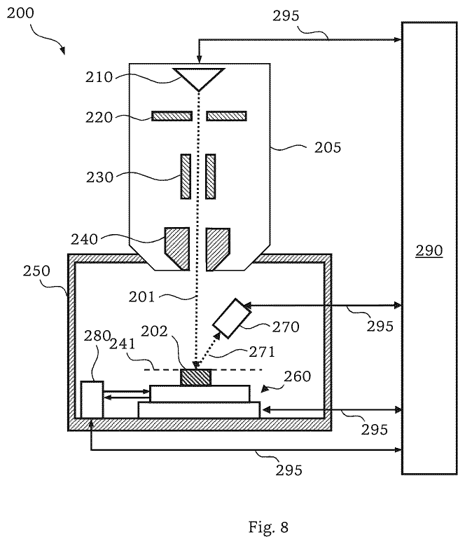

Embodiments of the disclosure are explained in greater detail below with reference to figures. FIG. 1 shows a flowchart illustrating a method for generating an image of a sample in accordance with one embodiment. The method shown is performed by a data processing apparatus 100 illustrated schematically in FIG. 7. Alternatively, the method shown can be performed by a controller 290 of a particle beam microscope 200 illustrated schematically in FIG. 8.

In step S1 (FIG. 1), interaction product measurement information is obtained. The interaction product measurement information represents results of a measurement of products 271 of an interaction of a particle beam 201 with the sample 202. The particle beam 201 is for example an electron beam, an ion beam or a light beam. The sample 202 is for example a semiconductor sample. The product 271 of the interaction between the particle beam 201 and the sample 202 can be for example: particles and/or radiation, such as backscattered electrons, secondary electrons, backscattered ions, secondary ions, x-ray radiation or light. Examples of interaction product measurement information representing results of a measurement of products of an interaction of a particle beam with the sample are: a temporal profile of measurement results, a number of detection events of interaction products, a rate of detection events of interaction products, an absolute or relative frequency of detection events of interaction products or combinations thereof. The interaction product measurement information comprises at least one result of a measurement of products 271 of an interaction. The interaction product measurement information can furthermore comprise time information indicating a point in time of the respective measurement.

Alternatively, the interaction product measurement information represents a variable based on results of a measurement of products 271 of an interaction of the particle beam 201 with the sample 202. That means that the variable is determined (calculated) using the results of the measurement and likewise changes if the results of the measurement change. Examples of interaction product measurement information based on results of a measurement of products of an interaction of a particle beam with the sample are: one or more mean values of a portion of the results of the measurement; one or more integrated or summed values of a portion of the results of the measurement; one or more values obtained by applying a calculation formula to a portion of the results of the measurement.

The interaction product measurement information can be obtained from a (volatile or non-volatile) data memory. In this case, the interaction product measurement information that has been previously stored in the data memory is read from the data memory. Examples of the data memory are the auxiliary memory 130 (see FIG. 7) or an external data memory. Alternatively, the interaction product measurement information can be obtained by carrying out the measurement of the products 271 of the interaction of the particle beam 201 with the sample 202 using an interaction product measurement measuring apparatus 270. The interaction product measurement measuring apparatus 270 is for example a measuring apparatus for measuring radiation or a measuring apparatus for measuring particles, such as charged particles.

In step S2 (FIG. 1), deflection information is obtained. The deflection information represents a deflection of the particle beam 201 during the measurement of the products 271 of the interaction. Examples of deflection information representing a deflection of the particle beam during the measurement of the products 271 of the interaction are: a temporal profile of the deflection, a target value of the deflection, a measured value of the deflection, a temporal profile of a target value or of a measured value of the deflection. The deflection can take place in one or more directions (dimensions). By way of example, the deflection is carried out in two directions. The deflection information comprises at least one value for each of the directions (dimensions) of the deflection. The deflection information can furthermore comprise time information indicating a point in time for carrying out the deflection in accordance with the values of the deflection.

Alternatively, the deflection information represents a variable based on the deflection of the particle beam 201 during the measurement of the products 271 of the interaction. That means that the variable is determined (calculated) using the deflection of the particle beam 201 during the measurement of the products 271 of the interaction and likewise changes if the deflection changes. The particle beam 201 is deflected (i.e. diverted) during the method in order to direct the particle beam 201 onto different locations of the sample 202 and thus to enable measurements of the interaction products for different locations of the sample 202. Examples of deflection information based on a deflection of the particle beam are: a computation variable obtained by transformation or mapping of the deflection; one or more mean values of a portion of the deflection; one or more integrated or summed values of a portion of the deflection; one or more values obtained by applying a calculation formula to a portion of the deflection.

The deflection information can be obtained from a (volatile or non-volatile) data memory. In this case, the deflection information that has been previously stored in the data memory is read from the data memory. Alternatively, the deflection information can be obtained by a controller, for example the controller 290 of the particle beam microscope 200 (see FIG. 8). As a further alternative, the deflection information can be obtained using a measurement of the deflection using a measuring apparatus for measuring the deflection of the particle beam 201.

In step S3 (FIG. 1), sample stage pose measurement information is obtained. The sample stage pose measurement information represents results of a measurement of a measurement variable during the measurement of the products 271 of the interaction, wherein the measurement variable is dependent on a spatial pose of a sample stage 260 carrying the sample 202. The fact that the measurement variable is dependent on the spatial pose of the sample stage 260 means that the measurement variable likewise changes if the spatial pose of the sample stage 260 changes. Examples of a measurement variable which is dependent on a spatial pose of a sample stage 260 carrying the sample 202 are: a position of the sample stage, an orientation of the sample stage, at least one coordinate of the position of the sample stage, at least one coordinate of the orientation of the sample stage, and a vibration of the sample stage or combinations thereof. Examples of sample stage pose measurement information representing results of a measurement of a measurement variable are: a temporal profile of the measurement variable, a spectrum of the measurement variable. The sample stage pose measurement can take place in one or more directions (dimensions). By way of example, the sample stage pose measurement is carried out in two directions. The two directions can span a plane which is oriented non-parallel (i.e. transversely, for example substantially perpendicularly) to the particle beam 201. The sample stage pose measurement information comprises at least one value representing a result of the measurement of the measurement variable for each of the directions (dimensions) of the sample stage pose measurement. The sample stage pose measurement information can furthermore comprise time information indicating a point in time for carrying out the sample stage pose measurement.

Alternatively, the sample stage pose measurement information represents a variable based on results of a measurement of a measurement variable during the measurement of the products 271 of the interaction. That means that the variable is determined (calculated) using the results of the measurement of the measurement variable during the measurement of the products 271 of the interaction and likewise changes if the results of the measurement of the measurement variable change. Examples of sample stage pose measurement information based on results of a measurement of a measurement variable are: one or more mean values of a portion of the results of the measurement; one or more integrated or summed values of a portion of the results of the measurement; one or more values obtained by applying a calculation formula to a portion of the results of the measurement; a computation variable obtained by transformation or mapping of the measurement variable; or a combination thereof.

The sample stage pose measurement information can be obtained from a (volatile or non-volatile) data memory. In this case, the sample stage pose measurement information that has been previously stored in the data memory is read from the data memory. Alternatively, the sample stage pose measurement information can be obtained via measurement of the measurement variable using a sample stage pose measuring apparatus 280. Examples of the sample stage pose measuring apparatus 280 comprise an interferometer, such as a laser interferometer, a vibration measuring apparatus and a capacitive sensor.

Without restricting the generality, it should be assumed as an example for the further description that the interaction product measurement information represents a number of detection events of secondary electrons per predetermined sampling time interval.

Furthermore, it should be assumed that the deflection information represents a temporal profile of an electrical voltage controlling the deflection. During the sampling time interval, the deflection is virtually constant in order to direct the particle beam 201 onto the same location of the sample 202 for the duration of the sampling time interval. After each sampling time interval, the deflection is changed in order to direct the particle beam 201 onto a different location of the sample 202 for the duration of the sampling time interval.

Furthermore, it should be assumed that the sample stage pose measurement information represents a temporal profile of electrical voltages representing a displacement of the sample stage 260 in two directions spanning a plane traversed by the particle beam 201 at an angle that is different from zero.

In step S4 (FIG. 1), a first transformation T1 is applied to the deflection information, thereby obtaining first location information representing an incidence location of the particle beam 201 on the sample 202 in a coordinate system of the deflection unit 230. In the present example, the temporal profile of the electrical voltage controlling the deflection is accordingly converted into a temporal profile of an incidence location of the particle beam 201 on the sample 202 in the coordinate system of a deflection unit 230.

In step S5, a second transformation T2 is applied to the sample stage pose measurement information, thereby obtaining second location information representing a position of the sample stage 260 (more precisely, a position of an upper section of the sample stage 260) in the coordinate system of the deflection unit 230. In the present example, a temporal profile of electrical voltages representing a displacement of the sample stage 260 in two directions is accordingly converted into a temporal profile of the (two-dimensional) position (of the upper section) of the sample stage 260 in the coordinate system of the deflection unit 230.

The term “coordinate system of the deflection unit 230” denotes a coordinate system which is rigid in relation to the deflection unit 230. That means that the deflection unit 230 and the coordinate system of the deflection unit 230 are always positioned identically with respect to one another and always oriented identically with respect to one another. Since the deflection unit 230 and the other components of the particle beam column 205 are rigid with respect to one another, any coordinate system of a component of the particle beam column 205 or the coordinate system of the particle beam column 205 itself can be used instead of the coordinate system of the deflection unit 230.

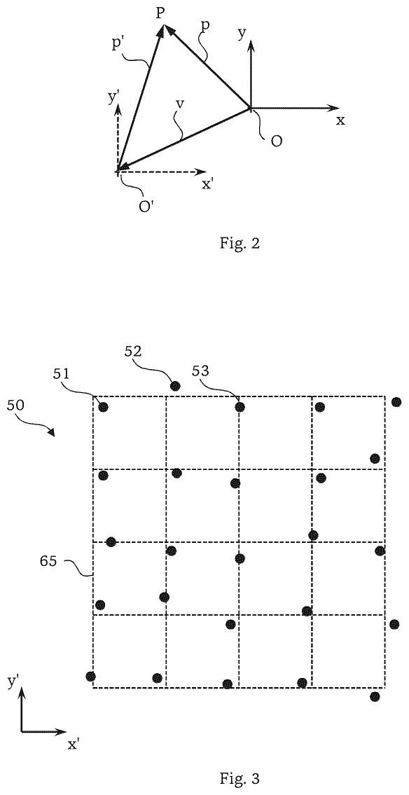

Using the first transformation T1 and the second transformation T2, for the deflection information and the sample stage pose measurement information, respective items of information in the same coordinate system are calculated (specifically the first location information and the second location information in the coordinate system of the deflection unit 230 in the present example). The items of information in the same coordinate system are comparable with one another. The meaning of the first location information and the second location information is explained below with reference to FIG. 2.

FIG. 2 shows one example of the coordinate system of the deflection unit 230 with the coordinates x and y and the origin O (referred to herein as coordinate system O). A vector p represents the first location information. The location P indicated by the vector p is the incidence location of the particle beam 201 on the sample 202 in the coordinate system O. In the coordinate system O, the incidence location is solely defined by the first location information. That means that the uncontrollable movement of the upper section of the sample stage 260 relative to the lower section of the sample stage (hence the uncontrollable movement of the upper section of the sample stage 260 in the coordinate system O) has no influence on the incidence location P in the coordinate system O.

FIG. 2 furthermore shows one example of a coordinate system of the sample 202 with the coordinates x′ and y′ and the origin O′ (referred to herein as coordinate system O′). The term “coordinate system of the sample 202” denotes a coordinate system which is rigid in relation to the sample 202. That means that the sample 202 and the coordinate system of the sample 202 are always positioned identically with respect to one another and always oriented identically with respect to one another. A vector v represents the second location information representing the position (of the upper section) of the sample stage 260 in the coordinate system O. The second location information is time-dependent and represents the position of the upper section of the sample stage 260 in the coordinate system O.

Step S6 (FIG. 1) involves calculating incidence locations of the particle beam 201 on the sample 202 in the coordinate system of the sample 202 using the first location information and the second location information. In FIG. 2, a vector p′ indicates the calculated incidence location of the particle beam 201 on the sample 202 in the coordinate system O′. As is illustrated in FIG. 2, the vector p′ can be calculated using the vectors p and v and the rules of vector addition.

In step S7, image points representing the incidence locations calculated in step S6 are calculated. The calculation of the image points is carried out for example such that a relative arrangement of the image points with respect to one another and a relative arrangement of the incidence locations with respect to one another are identical. That means that the relative arrangement of the image points differs from the relative arrangement of the incidence locations only in terms of uniform scaling, rotation or displacement. Alternatively, the incidence locations can be used as the image points.

In step S8, the image is generated. The image comprises the image points calculated in step S7, which are assigned values represented by or based on the interaction product measurement information.

FIG. 3 shows one example of a graphical representation of an image 50 calculated in step S8 as a scatter diagram. FIG. 3 furthermore shows a regular rectangular auxiliary grid 65, which merely serves for elucidating the image 50 but is not itself part of the image 50. The positions at the intersection points of the lines of the auxiliary grid 65 represent the first location information.

In the example of the auxiliary grid 65 shown, the first location information therefore comprises a multiplicity of positions with constant spacings in an x-direction and a y-direction.

The image 50 comprises the image points 51, 52, 53, etc. Each image point indicates a spatial position in the image. The image points are generally interpreted as locations on the sample. The image points are arranged irregularly on account of second location information assumed to be non-constant (i.e. varying second location information) (i.e. on account of an irregular movement of the sample stage 260), even though the first location information represents a regular incidence location in accordance with the auxiliary grid 65. Each of the image points 51, 52, 53, etc. is assigned a (at least one) value.

The method in accordance with FIG. 1 can furthermore comprise: displaying the calculated image as a graphical representation on a display device, wherein the value assigned to the respective image point is represented at each of the image points.

As is illustrated in FIG. 1, the image is calculated using the interaction product measurement information, using the deflection information and using the sample stage pose measurement information. To put it more precisely, the image points of the image are calculated using the deflection information and using the sample stage pose measurement information; and the calculated image points are each assigned a value of the interaction product measurement information. The sample stage pose measurement information is not used for controlling the deflection unit 230 of the particle beam microscope 200. The sample stage pose measurement information is not used for controlling the sample stage 260. Taking account of the sample stage pose measurement information when generating the image makes it possible to generate an image whose image points more accurately represent the incidence locations of the particle beam 201 on the sample 202, since the influence of the uncontrolled movement of the sample stage can be eliminated.

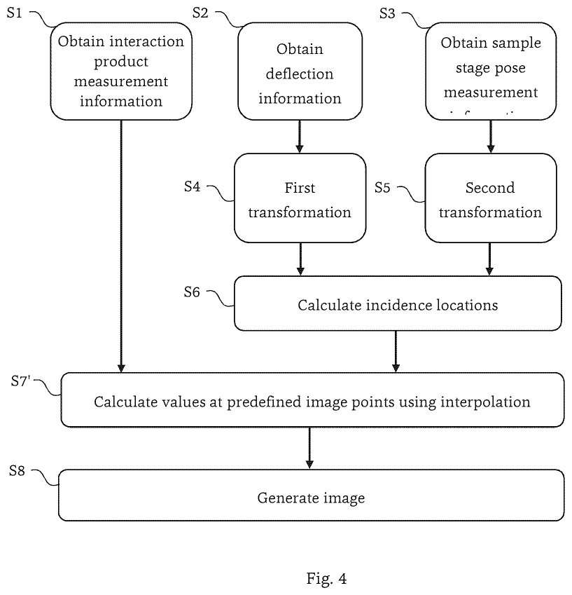

FIG. 4 shows a flowchart illustrating a method for generating an image 60 of a sample 202 in accordance with a further embodiment. The method shown in FIG. 4 differs from the method shown in FIG. 1 merely in that step S7 is replaced by step S7′. With regard to steps S1 to S6 and S8, reference is made to the description above.

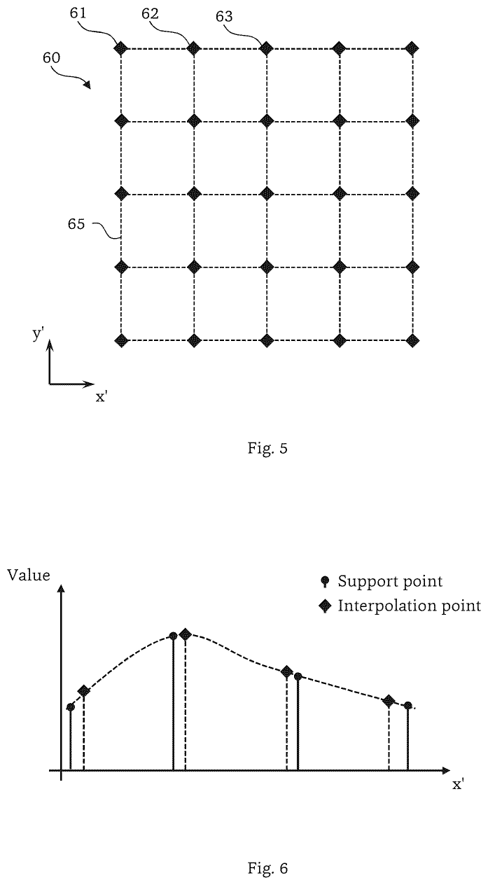

Step S7′ involves calculating values at predefined image points using an interpolation of the interaction product measurement information in which the incidence locations calculated in step S6 are used as support points. FIG. 5 shows one example of predefined image points 61, 62, 63, etc. of an image 60. The image points 61, 62, 63 are represented by rhombi. The image points 61, 62, 63, etc. lie at the intersection points of the lines of the auxiliary grid 65. Accordingly, the image points 61, 62, 63, etc. are distributed equidistantly in the x′-direction and in the y′-direction. Since the image points 61, 62, 63, etc. are predefined (by a user, for example) and in general therefore do not represent the incidence locations calculated in step S6, the interaction product measurement information is interpolated in order to calculate suitable values for the image points 61, 62, 63, etc. During the interpolation, the incidence locations calculated in step S6 are used as support points.

An example of an interpolation for explanation purposes is illustrated in FIG. 6. FIG. 6 shows an example of a one-dimensional interpolation in the x′-direction. Two- or three-dimensional interpolations can likewise be applied. A graph shown in FIG. 6 shows a position in the x-direction on the horizontal axis and a value corresponding to the interaction product measurement information on the vertical axis. Four incidence locations calculated in step S6 and values assigned to these incidence locations are represented by filled-in circles. The incidence locations are distributed irregularly in the x-direction, which should be expected in the case of an uncontrolled movement of the sample stage 260. Four rhombi indicate interpolation points, which are predefined and are distributed equidistantly in the x′-direction in accordance with the example in FIG. 5, and values assigned to the interpolation points. The values at the interpolation points are calculated by interpolation of the values at the support points. The calculated incidence locations serve as support points. The interpolation points correspond to the image points.

In step S8 (FIG. 4), the image points and the values determined for the image points by interpolation in step S7 are combined to form an image. In the example in FIG. 4, the image points are predefined image points, for example the image points 61, 62, 63, etc. represented by rhombi in FIG. 5. The values assigned to these image points were calculated by interpolation in step S7′.

As is illustrated in FIG. 4, the values at the image points of the image are calculated using the interaction product measurement information, using the deflection information and using the sample stage pose measurement information. To put it more precisely, incidence locations of the particle beam 201 on the sample 202 in a coordinate system of the sample 202 are calculated using the deflection information and using the sample stage pose measurement information; and the incidence locations are each assigned a value of the interaction product measurement information. On the basis of the calculated incidence locations and the values of the interaction product measurement information which are assigned to the incidence locations, values are calculated for a multiplicity of image points, which need not represent the incidence locations and can be predefined, wherein the calculation comprises an interpolation of the values of the interaction product measurement information which are assigned to the calculated incidence locations.

### Method for Operating a Particle Beam Microscope

Methods used to generate an image have been described with reference to FIGS. 1 to 6. The methods described below serve to prepare for image generation.

A first method for operating a particle beam microscope comprises: carrying out a measurement of products of an interaction of a particle beam with a sample; carrying out a deflection of the particle beam during carrying out the measurement of the products of the interaction; carrying out a measurement of a measurement variable during carrying out the measurement of the products of the interaction, wherein the measurement variable is dependent on a spatial pose of a sample stage carrying the sample; determining interaction product measurement information representing or based on results of the carried out measurement of the products of the interaction; determining deflection information representing or based on the carried out deflection; and determining sample stage pose measurement information representing or based on results of the carried out measurement of the measurement variable. These method steps have already been described in detail above. Reference is made to this description. The first method furthermore comprises: storing the determined interaction product measurement information, the determined deflection information and the determined sample stage pose measurement information in a data memory.

A second method for operating a particle beam microscope comprises: carrying out a measurement of products of an interaction of a particle beam with a sample; carrying out a deflection of the particle beam during carrying out the measurement of the products of the interaction; carrying out a measurement of a measurement variable during carrying out the measurement of the products of the interaction, wherein the measurement variable is dependent on a spatial pose of a sample stage carrying the sample; determining interaction product measurement information representing or based on results of the carried out measurement of the products of the interaction; determining deflection information representing or based on the carried out deflection; determining sample stage pose measurement information representing or based on results of the carried out measurement of the measurement variable; and calculating incidence locations of the particle beam on the sample in a coordinate system of the sample using the determined deflection information and the determined sample stage pose measurement information. These method steps have already been described in detail above. Reference is made to this description. The second method furthermore comprises: storing the determined interaction product measurement information and the calculated incidence locations in association with one another in a data memory.

The first and second methods for operating a particle beam microscope store in the data memory all items of information which are used for carrying out the image generation in accordance with the methods shown in FIGS. 1 and 4. Using the first and second methods described above, the processes of carrying out measurements of the interaction products, obtaining the deflection of the particle beam and carrying out the measurement of the measurement variable, firstly, and generating an image, secondly, can be carried out both temporally separately and using different apparatuses.

### Synchronization

In step S6 described above, the first location information determined from the deflection information and the second location information determined from the sample stage pose measurement information are computed with one another in order to calculate the incidence locations of the particle beam 201 on the sample 202 in the coordinate system of the sample 202. In order to improve the accuracy and validity of the calculated incidence locations, the initial data of the calculation, here the deflection information and the sample stage pose measurement information, should be synchronous data.

In step S8 described above, the image points calculated in step S7 on the basis of the incidence locations calculated in step S6 are assigned values represented by or based on the interaction product measurement information. In order to improve the accuracy and validity of the generated image, the initial data of the assignment, here the image points or incidence locations and the interaction product measurement information, should be synchronous data.

The interaction product measurement information, the deflection information and the sample stage pose measurement information can be data that are synchronous with one another. Data from different data sources are referred to as “synchronous” if the data represent events which happened at the same point in time or in the same time period or in predominantly overlapping time periods.

By way of example, digital values representing digitized analogue signals are generally “synchronous” if the analogue signals are digitized simultaneously. This can be realized for example by one analogue/digital converter configured to digitize a plurality of input signals simultaneously. Alternatively, this can be realized by a plurality of analogue/digital converters controlled by the same clock signal. The clock signal triggers an analogue/digital conversion of an input signal simultaneously in each of the plurality of analogue/digital converters. Consequently, analogue/digital conversions are carried out synchronously by the plurality of analogue/digital converters.

By way of example, a first processed value based on data of a first time period of a first data source (for example a mean value of data of the first time period of the first data source) and a second processed value based on data of a second time period of a second data source (for example a mean value of data of the second time period of the second data source) are deemed to be “synchronous” if the first time period and the second time period are identical or at least predominantly overlap. The point in time of the processing (for example a calculation of a mean value) is unimportant for the time period. Instead, the time period of the data taken as a basis for the processing is relevant.

If the interaction product measurement information, the deflection information and the sample stage pose measurement information are synchronous data, these can be used in the methods shown in FIGS. 1 and 4, without additional temporal interpolation.

However, it is not necessary for the interaction product measurement information, the deflection information and the sample stage pose measurement information to be synchronous data. Instead, the interaction product measurement information, the deflection information and the sample stage pose measurement information can be asynchronous data. Data from different data sources are referred to as “asynchronous” if the data represent events which happen at different points in time or in non-overlapping or predominantly non-overlapping time periods.

By way of example, digital values representing digitized analogue signals are generally “asynchronous” if the analogue signals are digitized at different points in time. This can be realized for example by a plurality of analogue/digital converters controlled by different clock signals. The clock signals each trigger an analogue/digital conversion of a respective input signal at different points in time in the plurality of analogue/digital converters. Consequently, analogue/digital conversions are carried out asynchronously by the plurality of analogue/digital converters.

By way of example, a first processed value based on data of a first time period of a first data source (for example a mean value of data of the first time period of the first data source) and a second processed value based on data of a second time period of a second data source (for example a mean value of data of the second time period of the second data source) are deemed to be “asynchronous” if the first time period and the second time period do not overlap or at least predominantly do not overlap. The point in time of the processing (for example a calculation of a mean value) is unimportant for the time period. Instead, the time period of the data taken as a basis for the processing is relevant.

If the interaction product measurement information, the deflection information and the sample stage pose measurement information are asynchronous data, it is advantageous to obtain synchronous data from the asynchronous data in order to improve the accuracy and validity of the image to be generated.

Synchronous data can be obtained from asynchronous data by temporal interpolation, for example. For this purpose, in the course of capture (for example measurement, digitization) of the data, a point in time of the data capture or a point in time of events underlying the data is in each case captured and stored together with the data.

If the interaction product measurement information represents a temporal profile of measurement results, for example, points in time at which the measurements of the measurement results were carried out are additionally captured and stored besides the measurement results (i.e. the data). By way of example, the points in time of the digitization of an analogue output signal of the interaction product measuring apparatus 270 are stored in addition to the (digital) measurement results. On the basis of the stored points in time and the (digital) measurement results, a value for the interaction products can be interpolated (or extrapolated) for any desired point in time. The same applies to the deflection information and the sample stage pose measurement information. In this way, it is possible to calculate an interpolation value for the interaction product measurement, the deflection and the sample stage pose measurement for any desired point in time. Even if the interaction product measurement information, the deflection information and the sample stage pose measurement information are asynchronous among one another, the temporal interpolation makes it possible to calculate synchronous data of these items of information, which can then be taken as a basis for the calculations of the methods in FIGS. 1 and 4.

### Data Processing Apparatus

FIG. 7 shows a hardware configuration of a data processing apparatus 100. The data processing apparatus 100 comprises a processor 110, which executes various processes, a main memory 120, which serves as a working area of the processor 110, an auxiliary memory 130, which stores various data used in the processes of the processor 110, an input device 140, an output device 150 and a communication device 160. The main memory 120, the auxiliary memory 130, the input device 140, the output device 150 and the communication device 160 are each connected to the processor 110 via buses 170.

The processor 110 comprises a central processing unit (CPU). The processor 110 executes a program P1 stored in the auxiliary memory 130, and thereby carries out various functions of the data processing apparatus 100.

The main memory 120 comprises a random access memory (RAM). The main memory 120 receives the program P1 loaded from the auxiliary memory 130. The main memory 120 serves as a working area of the processor 110.

The auxiliary memory 130 comprises a (volatile or non-volatile) memory, such as for example an EEPROM (“electrically erasable programmable read-only memory”). The auxiliary memory 130 stores the program P1 and various data used in processes of the processor 110. The auxiliary memory 130 provides the processor 110 with data to be processed by the processor 110, and stores data output by the processor 110 under the instructions of the processor 110.

The input device 140 serves for obtaining information from a user of the data processing apparatus 100. The input device 140 comprises for example an input key, a keyboard or a pointing device. The input device 140 forwards the obtained information to the processor 110.

The output device 150 serves for outputting information to a user of the data processing apparatus 100 or to other persons. The output device 150 comprises a monitor or a loudspeaker, for example. The output device 150 can be a touch-sensitive screen (“touchscreen”), for example, which also serves as the input device 140. The output device 150 outputs various items of information under the instructions of the processor 110.

The communication device 160 serves for communication with external apparatuses. The communication device 160 receives signals from external apparatuses and outputs data indicated by the signals to the processor 110. The communication device 160 transmits signals indicating data output by the processor 110 to external apparatuses.

The program P1 contains instructions which, when executed by the processor 110, cause the data processing apparatus 100 to carry out the methods described herein.

### Program

The program P1 can be executed on a customary computer. Such a program can be distributed by any desired procedure. By way of example, the program can be stored and disseminated in a non-volatile computer-readable recording medium, such as for example a CD-ROM (compact disc read-only memory), a DVD (digital versatile disc) or a memory card. The program can also be disseminated via a communication network, such as for example the Internet.

### Particle Beam Microscope

FIG. 8 shows an exemplary particle beam microscope 200. The particle beam microscope 200 can be a scanning electron microscope or a scanning ion microscope, for example.

The particle beam microscope 200 comprises a particle beam column 205. The particle beam column 205 comprises a particle source 210 for providing charged particles of a particle beam 201, for example electrons or ions, an acceleration electrode 220 for accelerating the particles of the particle beam 201, a deflection unit 230, comprising diverting coils and/or diverting electrodes, for example, for deflecting the particle beam 201, and an objective lens 240 for focusing the particle beam 201 into a focal plane 241.

The particle beam microscope 200 furthermore comprises a vacuum chamber 250, which is arranged on the particle beam column 205 and in which a sample stage 260 is arranged. The sample stage 260 is configured to carry the sample 202. The sample stage 260 can be configured to displace and rotate the sample 202. In the example shown, the sample stage comprises a lower section and an upper section. The sample 202 is rigidly mounted on the upper section. The upper section can be displaced and/or rotated relative to the lower section by controlled drives (not illustrated) in order thereby to be able to change the pose of the sample 202 relative to the particle beam column 205 in a controlled manner.

The particle beam microscope 200 furthermore comprises an interaction product measuring apparatus 270 for measuring interaction products 271 resulting from the interaction of the particle beam 201 with the sample 202. Interaction products can be for example: particles, such as charged particles, such as for example secondary electrons, backscattered electrons, secondary ions, backscattered ions; or radiation, such as for example light.

The particle beam microscope 200 furthermore comprises a sample stage pose measuring apparatus 280. The sample stage pose measuring apparatus 280 is configured to carry out a measurement of the measurement variable (physical variable that is dependent on a spatial pose of the sample stage 260). For example, the sample stage pose measuring apparatus 280 is configured to measure as the measurement variable a physical variable of a section of the sample stage 260 which is rigidly connected to the sample 202 and is dependent on the spatial pose of the section. The sample stage pose measuring apparatus 280 comprises for example an interferometer, such as a laser interferometer, a vibration measuring apparatus and/or a capacitive sensor. FIG. 8 illustrates a laser interferometer as an example of the sample stage pose measuring apparatus 280, which laser interferometer directs a laser beam onto the upper section of the sample stage 260, on which the sample 202 is rigidly arranged. A portion of the laser beam that is reflected at the upper section of the sample stage 260 is received by the laser interferometer and processed. An output signal of the laser interferometer (or of the sample stage pose measuring apparatus 280) is output via a communication line 295 to a controller 290 or a data processing apparatus 100.

The particle beam microscope 200 furthermore comprises the controller 290 for controlling the particle beam microscope 200 and the components thereof. The controller 290 furthermore serves as the data processing apparatus 100. Alternatively, the particle beam microscope 200 comprises a controller for controlling the particle beam microscope 200 and the components thereof and the data processing apparatus 100 as separate components. The controller 290 controls the particle source 210, the acceleration electrode 220, the deflection unit 230 and the objective lens 240 via one or more communication lines/control lines 295. The controller 290 controls the sample stage 260 via a communication line/control line 295.

The controller 290 controls the measuring apparatuses 270, 280 and obtains measurement results from the measuring apparatuses 270, 280 via one or more communication lines 295.

The particle beam microscope 200 can comprise one or more analogue/digital converters (not shown) which digitizes or digitize an analogue output signal of the interaction product measurement measuring apparatus 270, an analogue output signal of the sample stage pose measuring apparatus 280 and, if the deflection information represents or is based on an analogue signal, the analogue signal of the deflection information.

The digitization (i.e. analogue/digital conversion) of the aforementioned analogue signals can be carried out synchronously. That means that the digitization (i.e. analogue/digital conversion) of the aforementioned analogue signals is carried out simultaneously, such that the digital values generated represent synchronous events. The synchronous digitizations can be carried out for example by way of the digitizations being triggered by one and the same clock signal. The clock signal can be transmitted within the controller 290 to an analogue/digital converter in the controller 290 or via one of the communication lines/control lines 295 to an analogue/digital converter outside the controller 290 (for example in the interaction product measurement measuring apparatus 270 or in the sample stage pose measuring apparatus 280).

The digitization (i.e. analogue/digital conversion) of the aforementioned analogue signals can be carried out asynchronously. That means that the digitization (i.e. analogue/digital conversion) of the aforementioned analogue signals is not carried out simultaneously, such that the digital values generated represent asynchronous events. The asynchronous digitizations can be carried out for example by way of the digitizations being triggered by different clock signals.

The particle beam microscope 200 furthermore comprises one or more current sources and/or one or more voltage sources, which are not illustrated in the figures. The current sources and voltage sources are configured to supply the components of the particle beam microscope 200, for example electrodes for generating electric fields and coils for generating magnetic fields, with suitable electric voltages and electric currents. The current sources and voltage sources are controlled by the controller 290.

Embodiments of the disclosure can, but need not, comprise or implement all the steps of the methods described herein. That means that embodiments of the disclosure can comprise or implement just a portion of the steps of the methods described herein.

### LIST OF REFERENCE SIGNS

50, 60 Image
51 to 53, 61 to 63 Image points
65 Auxiliary grid
100 Data processing apparatus
110 Processor
120 Main memory
130 Auxiliary memory
140 Input device
150 Output device
160 Communication device
200 Particle beam microscope
201 Particle beam
202 Sample
205 Particle beam column
210 Particle source
220 Acceleration electrode
230 Deflection unit
240 Objective lens
241 Focal plane
250 Vacuum chamber
260 Sample stage
270 Interaction product measuring apparatus
271 Interaction product
280 Sample stage pose measuring apparatus
290 Controller
295 Communication and control lines

What is claimed is:

1. A method, comprising:
calculating an image of a sample via a data processing apparatus using:
a) interaction product measurement information representing or based on results of a measurement of products of an interaction of a particle beam with the sample;
b) deflection information representing or based on a deflection of the particle beam during the measurement of the products of the interaction; and
c) sample stage pose measurement information representing or based on results of a measurement of a measurement variable during the measurement of the products of the interaction of the particle beam with the sample,
wherein the measurement variable is dependent on a spatial pose of a sample stage carrying the sample.

2. The method of claim 1, wherein:
the image comprises: i) a multiplicity of different image points indicating positions in the image; and ii) values assigned to the image points; and
calculating the image of the sample comprises calculating the image points using the deflection information and the sample stage pose measurement information.

3. The method of claim 2, wherein, for each image point, calculating the image point comprises:
transforming a portion of the deflection information assigned to the image point into first location information representing an incidence location of the particle beam on the sample in a coordinate system of a deflection unit performing the deflection;
transforming a portion of the sample stage pose measurement information assigned to the image point into second location information representing a position of the sample stage in the coordinate system of the deflection unit;
calculating an incidence location of the particle beam on the sample in a coordinate system of the sample using the first location information and the second location information; and
calculating the image point based on the calculated incidence location or using the calculated incidence location as the image point.

4. The method of claim 3, wherein calculating the image comprises calculating the values at the image points using an interpolation of the interaction product measurement information in which the calculated incidence locations are used as support points.

5. The method of claim 1, wherein:
the image comprises: i) a multiplicity of different image points indicating positions in the image; and ii) values assigned to the image points; and
calculating the image comprises calculating the values using the interaction product measurement information, the deflection information and the sample stage pose measurement information.

6. The method of claim 1, further comprising obtaining, from a data memory, the interaction product measurement information, the deflection information and the sample stage pose measurement information.

7. The method of claim 1, further comprising performing the measurement of the products of the interaction of the particle beam with the sample using a measuring apparatus for measuring radiation or a measuring apparatus for measuring particles, in particular charged particles.

8. The method of claim 1, further comprising obtaining the deflection information from a controller or carrying out a measurement of the deflection using a measuring apparatus for measuring the deflection of the particle beam.

9. The method of claim 1, further comprising performing the measurement of the measurement variable using an interferometer, a vibration measuring apparatus and/or a capacitive sensor.

10. One or more machine-readable hardware storage devices comprising instructions that are executable by the data processing apparatus to perform operations comprising the method of claim 1.

11. A system, comprising:
a data processing apparatus; and
one or more machine-readable hardware storage device comprises instructions that are executable by the data processing apparatus to perform operations comprising the method of claim 1.

12. The system of claim 11, further comprising a particle beam microscope.

13. A method of operating a particle beam microscope, the method comprising:
measuring products of an interaction of a particle beam with a sample;
deflecting the particle beam while measuring the products;
measuring a measurement variable while measuring the products, the measurement variable being dependent on a spatial pose of a sample stage carrying the sample;
determining interaction product measurement information representing or based on results of the measurement of the products;
determining deflection information representing or based on the deflection;
determining sample stage pose measurement information representing or based on results of the measured measurement variable; and
storing, in a data memory, the determined interaction product measurement information, the determined deflection information and the determined sample stage pose measurement information.

14. One or more machine-readable hardware storage devices comprising instructions that are executable by the data processing apparatus to perform operations comprising the method of claim 13.

15. A system comprising:
a data processing apparatus; and
one or more machine-readable hardware storage device comprising instructions that are executable by the data processing apparatus to perform operations comprising the method of claim 13.

16. The system of claim 15, further comprising a particle beam microscope.

17. A method of operating a particle beam microscope, the method comprising:
measuring measurement of products of an interaction of a particle beam with a sample;
deflecting the particle beam while measuring the products;
measuring a measurement variable while measuring the products, the measurement variable being dependent on a spatial pose of a sample stage carrying the sample;
determining interaction product measurement information representing or based on results of the measured products of the interaction;
determining deflection information representing or based on the deflection;
determining sample stage pose measurement information representing or based on results of the measured measurement variable;
calculating incidence locations of the particle beam on the sample in a coordinate system of the sample using the deflection information and the sample stage pose measurement information; and
storing, in a data memory, the determined interaction product measurement information and the calculated incidence locations in association with one another.

18. One or more machine-readable hardware storage devices comprising instructions that are executable by the data processing apparatus to perform operations comprising the method of claim 17.

19. A system comprising:
a data processing apparatus; and
one or more machine-readable hardware storage device comprising instructions that are executable by the data processing apparatus to perform operations comprising the method of claim 17.

20. The system of claim 19, further comprising a particle beam microscope.
